(19) United States
(12) Patent Application Publication
(10) Pub. No.: US 2025/0116728 A1
(43) Pub. Date: Apr. 10, 2025

(54) OPEN FAULT DETECTION FOR POWER CONVERTERS

(71) Applicant: TEXAS INSTRUMENTS INCORPORATED, DALLAS, TX (US)

(72) Inventors: Nischal R, CHIKKABALLAPUR (IN); Dattatreya Baragur SURYANARAYANA, BANGALORE (IN); Bikash PRADHAN, BANGALORE (IN); Vikram GAKHAR, BANGALORE (IN); VishnuVardhan REDDY J, BANGALORE (IN); Preetam TADEPARTHY, BANGALORE (IN)

(21) Appl. No.: 18/585,853

(22) Filed: Feb. 23, 2024

(30) Foreign Application Priority Data
Oct. 4, 2023 (IN) 202341066396

(51) Int. Cl. G01R 31/54; H02H 7/12; H02M 3/335

(52) U.S. Cl. CPC G01R 31/54; H02H 7/1213; H02M 3/33576

(57) ABSTRACT

An example multiphase power converter circuit includes a first power stage is configured to provide a first phase output signal at a first switching output based on a first control signal. The first power stage includes first open fault detection circuitry configured to disable detecting and/or reporting of an open fault condition responsive to the first control signal. A second power stage is configured to provide a second phase output signal at a second switching output based on a second control signal. The second power stage includes second open fault detection circuitry configured to enable detecting and/or reporting of the open fault condition responsive to the second control signal having a value to turn off the second power stage. The second open fault detection circuitry is further configured to detect the open fault condition based on a voltage at the second switching output.

### RELATED APPLICATION

This application claims priority from Indian Provisional Patent Application Serial No. 202341066396, filed 4 Oct. 2023, which is incorporated herein by reference in its entirety.

### TECHNICAL FIELD

This description relates to open fault detection power converters.

### BACKGROUND

There are a variety of different power converter topologies. For example, multiphase buck convertors are evolving and are being used to support high current demand with steep load transients. The load transient is largely dependent on the output capacitor bank which is adapted to prevent faster current rise. A trans-inductor voltage regulator (TLVR) topology can be used in conjunction with multiphase power converters to help reduce load transients. Multiphase converters using the TLVR as well as other topologies can experience faults, which can reduce performance as well as adversely affect loads.

### SUMMARY

One described example relates to a circuit that includes first and second power stages. The first power stage includes first switching circuitry having a first control input and a first switching output. The first power stage also includes first open fault detection circuitry having first detection input and a first reference input, in which the first detection input is coupled to the first switching output and the first reference input is coupled to a reference voltage terminal. The second power stage includes second switching circuitry having a second control input and a second switching output. The second power stage also includes second open fault detection circuitry having third and fourth inputs, in which the third input is coupled to the second switching output and the fourth input is coupled to the reference voltage terminal.

Another described example relates to a multiphase power converter circuit that includes first and second power stages. The first power stage is configured to provide a first phase output signal at a first switching output based on a first control signal. The first power stage includes first open fault detection circuitry configured to disable detecting and/or reporting of an open fault condition responsive to the first control signal having a value to turn on the first power stage. The second power stage is configured to provide a second phase output signal at a second switching output based on a second control signal. The second power stage includes second open fault detection circuitry configured to enable detecting and/or reporting of the open fault condition responsive to the second control signal having a value to turn off the second power stage. The second open fault detection circuitry is further configured to detect the open fault condition based on a voltage at the second switching output.

Another described example relates to a circuit that includes a power stage, which includes switching circuitry and open fault detection circuitry. The switching circuitry is configured to provide a voltage at a switching output responsive to a control signal. The open fault detection circuitry includes a comparator configured to provide a comparator output signal indicating a detected open fault condition in based on a reference voltage and the voltage at the switching output. The open fault detection circuitry also includes phase detection control logic configured to enable the open fault detection circuitry to provide an open fault detection signal indicating the detected open fault condition responsive to the control signal having a value to turn off the switching circuitry.

### BRIEF DESCRIPTION OF THE DRAWINGS

FIG. 1 is a schematic diagram illustrating an example multiphase power converter circuit.

FIG. 2 is a block diagram illustrating an example fault detection circuit.

FIG. 3 is a block diagram illustrating another example fault detection circuit.

FIGS. 4, 5, 6, and 7 are signal diagrams illustrating signals for different operating conditions for the circuitry of FIGS. 1-3.

FIG. 8 is a circuit diagram illustrating an example multiphase power converter

FIG. 9 is a block diagram illustrating a power system for a computing apparatus implementing an example multiphase power converter.

### DETAILED DESCRIPTION

This description relates generally to circuitry and systems that detect open fault conditions for power converter systems.

As an example, a power stage includes switching circuitry and open fault detection circuitry. The switching circuitry can include one or more switches (e.g., arranged as a half-bridge or other switching topology) configured to provide a switching voltage at a switching output responsive to a control signal (e.g., a pulse-width modulated (PWM) signal provided by a controller). The open fault detection circuitry can include a comparator and detection logic. The comparator can be configured to provide a comparator output signal representative of an open fault condition detected based on a reference voltage and the voltage at the switching output. The logic can be configured to control (e.g., selectively enable or disable) the detecting and/or reporting of an open fault condition by the power stage. For example, the detection logic enables the power stage to provide an open fault detection signal representative of a detected open fault condition responsive to the control signal having a value to turn off the switching circuitry, such as during startup of the power converter. In another example, the detection logic circuitry is configured to disable the power stage from detecting and/or reporting an open fault condition responsive to the control signal having a value to turn on the first power stage.

As a further example, a multiphase power converter can include multiple instances of the power stage, in which each instance of the power stage (also referred to as a phase) is configured to provide a respective phase voltage. A controller thus can provide control signals to the power stages to regulate a voltage at an output of the power converter. For example, each power stage can be implemented as a respective integrated circuit (ICs) having inputs and outputs coupled to the controller for receiving a respective control signal and sending an open fault detection signal to the controller. Further, the power converter can implement a trans-inductor voltage regulator (TLVR) topology, in which the switching output of each power stage is coupled to a primary winding of a respective transformer having primary and secondary windings. In the TLVR topology, the secondary windings of the respective transformers of a given power loop are coupled in series with a compensation inductor to provide a compensation path to reduce transients. The open fault detection circuitry of each power stage thus can detect an open fault condition in the compensation path and report the detected fault condition to the controller. In examples where a given power stage includes sensing circuitry, such as configured to sense current and/or temperature, the given power stage can provide the open fault detection signal to a same output terminal that is also used by the sensing circuitry to provide a measure of the condition sensed by such sensing circuitry. In this way, the open fault detection circuitry can reliably detect whether or not the open fault condition exists and signal the detected fault to the controller, and the controller can take appropriate protective action, such as deactivating (e.g., turning off) an input power supply voltage or otherwise reducing damage to the power converter and/or load to which power is being supplied.

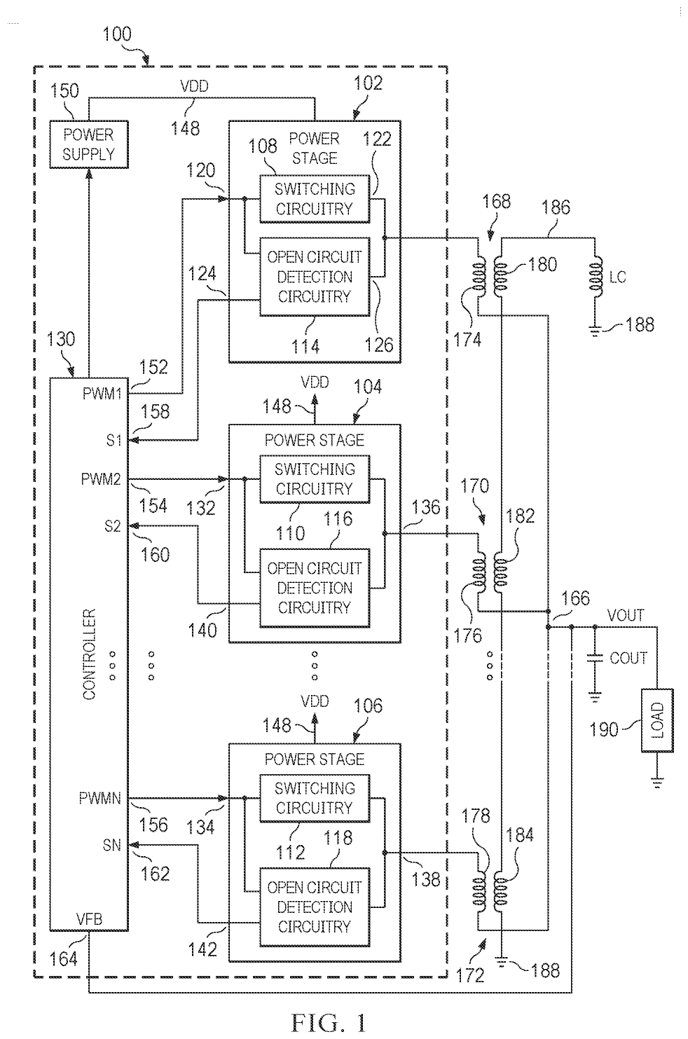

FIG. 1 is a schematic diagram illustrating an example multiphase power converter circuit 100. The power converter circuit 100 includes a plurality of power stages 102, 104, and 106, shown as power stages 1 through N, where N is a positive integer greater than or equal to two denoting the number of power stages. Each of the power stages 102, 104, and 106 includes switching circuitry 108, 110, 112 and open circuit detection circuitry 114, 116, and 118. As described herein, in some examples, each of the power stages 102, 104, and 106 can also include other circuitry configured to perform other functions, such as including circuitry to sense one or more operating conditions (e.g., temperature, current, voltage or the like).

In the example of FIG. 1, the power stage 102 has a control input 120, a switching output 122, and a report output 124. The switching circuitry 108 has an input coupled to the control input 120 and an output coupled to the switching output 122. The open fault detection circuitry 114 has a detection input 126 coupled to the switching output 122 and an output coupled to the report output 124. The switching circuitry 108 is configured to provide a phase voltage at the switching output 122 based on a signal at the control input 120. For example, the switching circuitry 108 is a half-bridge that includes transistors (e.g., field effect transistors) configured to provide the phase voltage responsive to pulse-width modulated (PWM) control signals provided by a controller 130.

The open fault detection circuitry 114 is configured to detect an open fault condition based on a voltage at the switching output 122. In an example, the open fault detection circuitry 114 is further configured to selectively enable or disable detecting and/or reporting of an open fault condition at the report output 124 based on the control signal at 120. For example, the open fault detection circuitry 114 is configured to disable detecting and/or reporting or an open fault condition at 124 responsive to the control signal at 120 having a value (or change in value) to turn on the power stage 102. The open fault detection circuitry 114 is configured to enable detecting and/or reporting of the open fault condition at 124 responsive to the control signal having a value (or change in value) to turn off the power stage.

In an example, each of the power stages 102, 104, and 106 is implemented as an instance of a respective IC configured to provide a respective phase voltage of the power converter circuit 100. Therefore, each of the other N−1 power stages 104 and 106 can be implemented in the manner described with respect to the power stage 102. That is, each of the power stages 106 and 106 has a respective control input 132, 134, a respective switching output 136, 138 and a respective report output 140, 142. The open fault detection circuitry 116 and 118 also has a detection input 144, 146 coupled to the respective switching output 136, 138 for detecting the open fault condition as described herein. In the example of FIG. 1, each of the power stages 102, 104 and 106 also has a respective power input terminal coupled to a supply voltage output 148. For example, a power supply 150 is configured to provide a supply voltage at the supply voltage output 148, such as a regulated DC voltage VDD.

The controller 130 has control outputs 152, 154, and 156 and sense terminals 158, 160, and 162, shown as S1, S2 through SN. Each of the control outputs 152, 154, and 156 is coupled to a respective control input 120, 132, and 134 of the power stages 102, 104, and 106. Each sense terminals 158, 160, 162 is coupled to a respective report output of the power stages 102, 104, and 106. The controller 130 has a feedback input 164 coupled to an output terminal 166 of the power converter circuit 100. The controller 130 is configured to provide control signals at 152, 154, and 156 to regulate a voltage VOUT at the output terminal 166. For example, the control signals at 152, 154, and 156 are pulse-width modulated (PWM) control signals provided selectively turn on and turn off the respective power stages 102, 104, and 106 for providing respective phase voltages at their phase outputs 122, 136, and 138, which combine to provide VOUT at the output terminal 166.

As a further example, the power converter circuit 100 is implemented according to the TLVR topology so that a respective transformer 168, 170, and 172 is associated with each power stage 102, 104, and 108. As illustrated in FIG. 1, a primary winding 174 of the transformer 168 is coupled between the switching output 122 and the output terminal 166. A primary winding 176 of the transformer 170 is coupled between the switching output 136 and the output terminal 166. And a primary winding 178 of the transformer 172 is coupled between the switching output 122 and the output terminal 166. Each of the transformers 168, 170, and 172 also has a respective secondary winding 180, 182, and 184 coupled in series with a compensation inductor LC to define a compensation path 186, which can be coupled between ground terminals 188. For example, the compensation path is configured to reduce transients at the output terminal 166 by dissipating current, which is induced from the primary to the secondary windings, through LC in the compensation path 186.

In the example of FIG. 1, a load 190 is coupled to the output terminal 166 in parallel with a capacitor COUT. If an open fault condition occurs in the compensation path 186, however, the remaining parts of circuit 100 generally cannot address the desired transient. Such transients during the open fault condition can degrade performance of the load 190 or even damage the load. This can be of particular concern for sensitive loads, such as servers including a number of one or more processor cores. The open fault detection circuitry is applicable to a multiphase power converter that could be used to supply power for any type of load.

The open fault detection circuitry 114, 116, and 118 of at least one power stage is configured to detect an open fault condition in the compensation path 186 based on a voltage at the respective switching output 122, 136, and 138 and responsive to the respective power stage being turned off during a startup (e.g., power-up) mode of the converter circuit 100. If there is no fault condition in the compensation path 186, the voltage at the respective switching output 122, 136, and 138 when the power stage is turned off will have a first expected voltage. For example, when there is no fault condition, a current will be induced from the secondary to the primary windings to provide corresponding voltage drop across the body diode of a low-side transistor of the switching circuitry 108, 110, 112, such as −0.7 V across the body diode. If there is a fault condition in the compensation path 186, however, the voltage at the respective switching output 122, 136, and 138 when the power stage is turned off will remain unchanged (e.g., at 0 V) because there is no current in the secondary winding to induce the current in the respective primary winding.

In some examples, the open fault detection circuitry 114, 116, and 118 can be configured to control whether a respective power stage 102, 104, 106 can detect and/or report an open fault condition. For example, the open fault detection circuitry 114, 116, and 118 is configured to enable the respective power stage 102, 104, 106 to detect an open fault condition and/or provide an open fault detection signal at the report output 124, 140, 142 responsive to the control signal at 120, 132, 134 commanding the respective switching circuitry 108, 110, 112 to turn off. In another example, the open fault detection circuitry 114, 116, 118 is configured to disable the power stage 102, 104, 106 from detecting and/or reporting an open fault condition at the report output 124, 140, 142 responsive to the control signal at 120, 132, 134 commanding the respective switching circuitry 108, 110, 112 to turn on. That is, when a given power stage 102,104, 106 is off during startup, the given power stage is operative to detect and/or report a detected fault. Conversely, when a given power stage is turned on during startup, the given power stage is disabled from detecting and/or reporting the occurrence of a detected fault. In this way, the control signal at 152, 154 and 156 can operate as a handshake mechanism between the controller 130 and the power stages 102, 104, and 106 to control which power stages 102, 104, 106 can and cannot detect/report an open fault condition. In response to receiving an open fault detection signal at one or more the sense inputs 158, 160 and 162, the controller 130 is configured to turn off the supply voltage VDD provided to the supply voltage terminal 148. For example, the controller 130 can turn off the power supply 150 and/or no longer provide PWM signals to activate the power stages 102, 104, 106. Alternatively, or additionally, the controller 130 can disconnect the supply voltage terminal 148 from the power supply, such as by opening a switch (not shown) between the power supply terminal 148 and the power stages 102, 104, and 106. The controller 130 can also record the fault condition in a log (e.g., memory), generate a fault alert to a user and/or take other corrective action responsive to detecting the open fault condition.

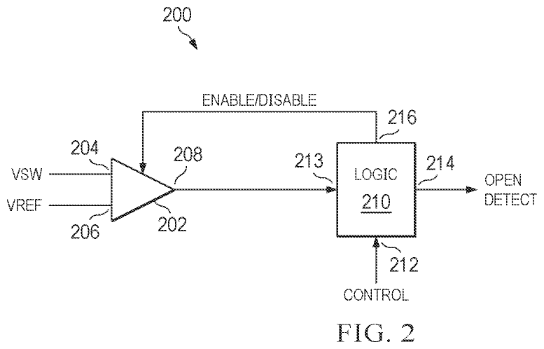

FIG. 2 is a block diagram illustrating an example open fault detection circuit 200. The open fault detection circuit 200 is an example of the open fault detection circuitry 114, 116, 118 described with respect to FIG. 1. Accordingly, the description of FIG. 2 also refers to FIG. 1. The open fault detection circuit 200 includes a comparator 202 having comparator inputs 204 and 206 and a comparator output 208. The comparator input 204 is coupled to a switching output 122, 136, 138 of the respective power stage 102, 104, 106 to receive a respective switching voltage VSW. The other comparator input 206 is coupled to a reference voltage terminal. For example, the comparator input 206 receives a reference voltage VREF (e.g., a DC threshold voltage) from a voltage reference generator. The open fault detection circuit 200 also includes logic circuitry 210 having logic inputs 212 and 213, a logic output 214, and an enable output 216.

In the example of FIG. 2, the comparator 202 is configured to provide a comparator output signal at the comparator output 208 based on comparing a switching voltage signal VSW at 204 relative to a reference voltage signal VREF at 206. For example, the reference voltage VREF is a DC voltage set to a threshold value that is less than an expected body diode voltage (e.g., VREF can range between 0 V and −0.5 V, such as −0.3 V). The switching voltage signal VSW is a voltage at a switching output of a respective power stage. The comparator 202 thus provides the comparator output signal at 208 to indicate the open fault condition responsive to VSW exceeding VREF. The logic circuitry 210 is configured to control reporting of the open fault condition based on the comparator output signal at 208 and the control signal at 212. The enable output 216 is coupled to a voltage supply input of the comparator 202, and that the logic circuitry 210 is configured to provide a logic signal at 216 having a DC voltage to enable or disable the comparator 202 based on the control signal at 212. The logic circuitry 210 can enable the comparator 202 responsive to the control signal at 212 having a value (e.g., one or a sequence of values) to turn off the respective power stage and disable the comparator responsive to the control signal having another value to turn on the respective power stage. The open fault detection circuit 200 thus is configured to provide an open fault detection signal at the logic output 214 based on the switching signal at 204 and the control signal at 212. The open fault detection circuit 200 further can be configured to implement the open fault detection and reporting functions during a startup mode of the respective power stage, such as at power up, and disable such functionality during normal operation.

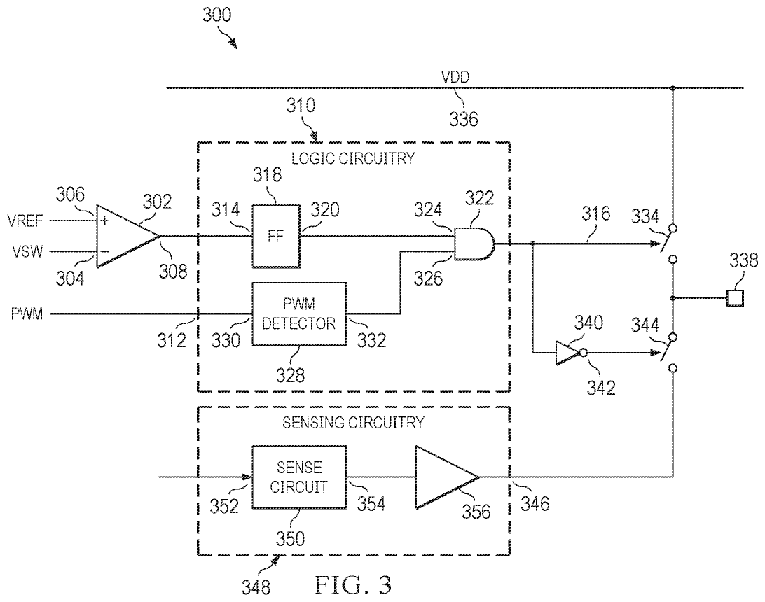

FIG. 3 is a block diagram illustrating another example open fault detection circuit 300. The open fault detection circuit 300 is another example of the open fault detection circuitry 114, 116, 118, and 200 described with respect to FIGS. 1 and 2. Accordingly, the description of FIG. 3 also refers to FIGS. 1 and 2. The open fault detection circuit 300 includes a comparator 302 having comparator inputs 304 and 306 and a comparator output 308. For example, the comparator input 304 is coupled to a switching output 122, 136, 138 of a respective power stage 102, 104, 106 to receive a respective switching voltage VSW. The other comparator input 306 is coupled to a reference voltage terminal, such as to receive a reference voltage VREF. The comparator 302 is configured to provide a comparator output signal at the comparator output 308 indicating an open fault condition based on the switching voltage signal VSW at 304 and the reference voltage signal VREF at 306.

The open fault detection circuit 300 also includes logic circuitry 310 having logic inputs 312 and 314, and a logic output 316. In the example of FIG. 3, the logic circuitry 310 includes a flip-flop (e.g., a latch or sample-hold circuit) 318 having an input coupled to the logic input 314 and an output 320. The flip-flop 318 is configured to provide a logic output representative of the comparator output at 308. An AND-gate 322 has first and second inputs 324 and 326, in which the first input 324 is coupled to the output 320 and the second input 326 is coupled to an output of PWM detector logic 328. The PWM detector logic 328 has an input 330 coupled to the logic input 312 to receive a PWM signal, which is provided by a controller (e.g., controller 130) to control a respective power stage that includes the open fault detection circuit 300. The PWM detector logic 328 is configured to detect whether the PWM signal at 312 has a value (e.g., one or a sequence of values) to turn off the respective power stage or a value to turn on the respective power stage. The PWM detector logic 328 thus can provide a logic signal at an output 332 responsive to detecting that the PWM signal at 312 is commanding the respective power stage to turn off. The logic signal at 332 thus can enable (or disable) the reporting of an open fault condition based on the PWM signal at 312.

In some examples, the controller 130 is configured to provide that PWM signal as a tri-state PWM signal having a tri-state, a low state, and a high state. The PWM detector logic 328 is configured to provide a detection logic signal at 332 based on the PWM signal at 330. For example, the PWM detector logic is configured to provide a logic high at output 332 responsive to detecting a transition from the tri-state to the low state, which commands the respective power state to turn off. The PWM detector logic 328 can also be configured to provide a logic low at output 332 responsive to detecting a transition from the tri-state to the high state, which commands the respective power state to turn on. The AND-gate 322 is configured to provide a logic signal at the output 316 responsive to logically ANDing the comparator output, which is provided by the flip-flop 318 at 320, with the signal provided at 332 by the PWM detector logic 328.

A switch (e.g., a transistor, such as a field effect transistor (FET)) 334 is coupled between a power supply terminal 336 and a report terminal 338. The report terminal 338 can be coupled to a sense input of the controller (e.g., controller 130). For example, a power supply (e.g., power supply 150) is configured to provide a supply voltage VDD at the power supply terminal 336 (e.g., terminal 148). The switch 334 has a control input coupled to the output 316, and the switch is configured to couple the report terminal 338 to the power supply terminal 336 responsive to the logic signal provided by the AND-gate 322. For example, the open fault detection circuit 300 is configured to provide the power supply voltage VDD at the report terminal 338 to indicate an open fault condition has been detected responsive to the comparator 302 detecting the open fault condition and the PWM detector logic 328 detecting a tri-state to low state transition in the PWM signal at 312. If both conditions are not met (e.g., no open fault condition detected and/or no tri-state to low state transition in the PWM signal), the open fault detection circuit 300 can effectively disable the first open fault detection circuit from reporting the open fault condition at the output terminal.

In the example of FIG. 3, the output 316 is also coupled to an input of an inverter 340, which has an output 342 coupled to a control input of another switch 344. The switch 344 is coupled between the report terminal 338 and an output 346 of sensing circuitry 348. The sensing circuitry 348 has a sense circuit 350 having an input 352 and an output 354. The sense circuit 350 can receive a signal or other stimulus, corresponding to a condition being sensed at the input 352, and provide a sensor signal at the output 354 representative of the sensed condition. As an example, the sense circuit 350 can be configured to sense voltage, current, temperature and/or another condition (e.g., an operating condition of the power stage or an environmental condition of or around the power stage). The sensing circuitry 348 can also include an amplifier 356 having an input coupled to the output 354 and an output coupled to the output of the sensing circuitry 348. The amplifier 356 can be configured to amplify the sensor signal at 354 to provide an amplified sensor signal at the output 346. The inverter 340 is configured to invert the logic output at 316 to control the switch 344 responsive to an inverted version of the logic signal at 316 (e.g., close the switch). The switch 344 is configured to couple the report terminal 338 to the output 346 of sensing circuitry 348 responsive to the inverted logic signal provided at 342. As result, the report terminal 338 is operative to provide either a signal having a value (e.g., VDD) indicative of a detected open fault condition or a signal having a value representative of a condition sensed by the sensing circuit 350.

As described herein, the controller (e.g., controller 130) can be configured to determine the occurrence of an open fault condition or determine the measure of the sensed condition based on the signal at the report terminal 338. For example, the controller can be configured to identify and use a first range of values in the signal at 338 (e.g., a voltage below a given voltage) for determining a measure of the sensed condition and a second range of values in the signal at 338 (e.g., a voltage, such as VDD, which is above the given voltage) for detecting the open fault condition.

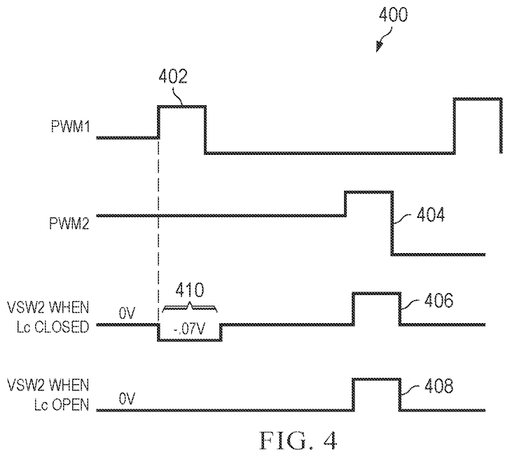

FIGS. 4-7 are example signal diagrams illustrating various signals to demonstrate how the circuits 100, 200, and 300 can perform open fault detection and related functions. Accordingly, the description of FIGS. 4-7 also refers to FIGS. 1-3. FIG. 4 is a signal diagram 400 that includes first and second PWM signals 402 and 404 at control inputs 120 and 132, respectively. The signal diagram also includes the switching signal 406 and 408 at the switching output 136, in which the signal 406 illustrates VSW when the compensation path 186 is closed (i.e., no open fault condition) and the signal 408 illustrates VSW at the same output 136 during an open fault in the compensation path.

For example, at startup, the PWM signal 402 goes high to turn on the first power stage 102, and the PWM signal 404 is tristated (e.g., at mid-voltage) to turn off the second power stage 104. Responsive to the activation of the first power stage 102, current flows through the primary winding 174, which induces current in the associated secondary winding 180. The current induced in the secondary winding 180 also flows in the compensation path 186 through the secondary winding 182, which induces current in the primary winding 176 and causes a voltage drop across the body diode of a low-side transistor of the switching circuitry 110 of the second power stage 104. The voltage drop across the body diode of the low-side transistor (e.g., about 0.7 V) provides a corresponding voltage drop, shown during time interval 410, in the switching signal 406. In contrast, during an open fault in the compensation path, current cannot flow to induce the current across the primary winding 176 of the second power stage 104. As a result, the switching signal 408 does not experience the voltage drop across the body diode, but instead remains unchanged. As described herein, the open fault detection circuitry can use the differences between signals 406 and 408 at startup to detect whether the open fault condition exists.

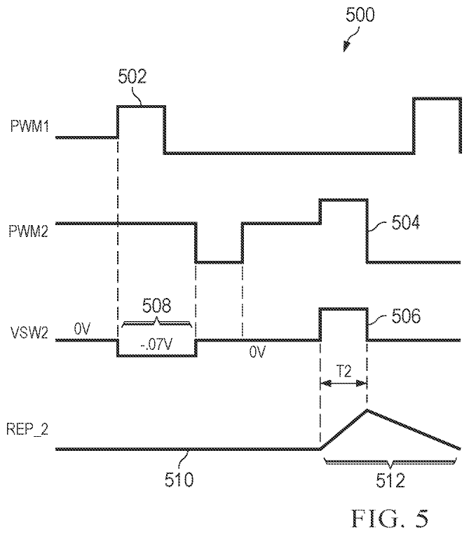

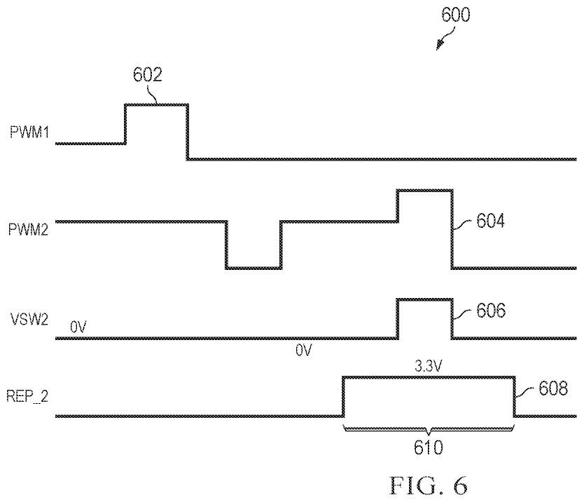

FIGS. 5 and 6 illustrate additional signal diagrams 500 and 600, which will be described with respect to FIGS. 1 and 3. The signal diagram 500 of FIG. 5 includes first and second PWM signals (PWM1 and PWM2) 502 and 504, which are received at control inputs 120 and 132, respectively. The signal diagram 500 also includes the switching signal (VSW2) 506 at the switching output 136, 306 of the second power stage in the absence of an open fault condition in the compensation path 186 (e.g., the compensation path 186 is closed). Accordingly, the signal 506 includes a voltage drop, shown at 508, such as representative of a body diode drop across a low-side transistor of the second power stage 104, as described herein. The signal diagram 500 also shows a signal (REP_2) 510 at the report output 140, 338 of the second power stage 102 when no fault is detected and the report output 140, 338 is coupled to the output 346 of the sensing circuitry 348 (e.g., to define a respective terminal of an IC). In an example, the signal 510 illustrates a sensed current, shown at 512, which is provided by the second power stage 104 when the power stage is turned on during time T2 responsive to the PWM signal 504.

The signal diagram 600 of FIG. 6 shows the same signals as FIG. 5 but during an open fault condition in the compensation path 186 (e.g., the compensation path 186 is open). FIG. 6 includes first and second PWM signals (PWM1 and PWM2) 602 and 604 at control inputs 120 and 132, respectively, the switching signal (VSW2) 606 at the switching output 136, 306 of the second power stage. Accordingly, the signal 606 remains unchanged (e.g., at 0 V) during and after the first power stage is activated to provide a phase voltage at its switching output 122. As a result, the report signal (REP_2) 608 at the report output 140, 338 of the second power stage 102 goes high (e.g., to VDD), shown at 610, responsive detecting the open fault condition. For example, when the open fault is detected by the comparator 302 and the PWM signal at 312 transitions from tristate to low, the report output 140, 338 is coupled to the supply terminal 336 so VDD is provided at the report output 610.

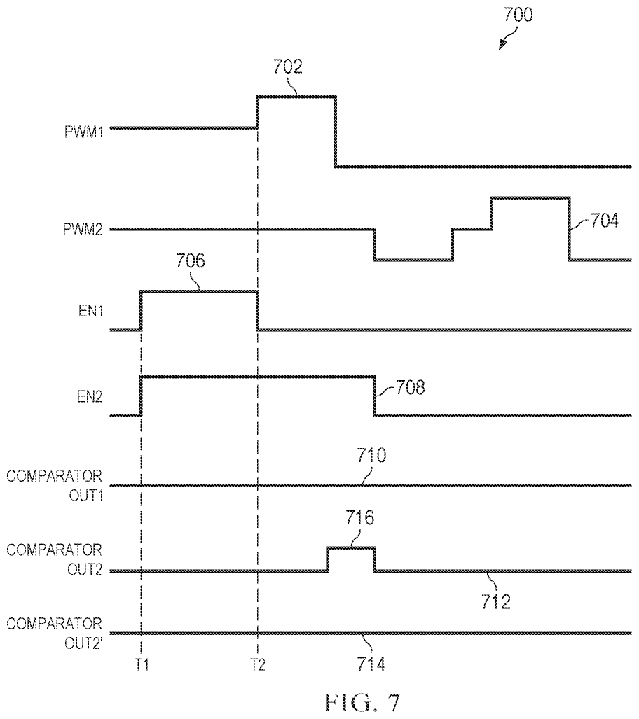

FIG. 7 is a signal diagram 700, which will be described with respect to FIGS. 1 and 2. The signal diagram 700 includes first and second PWM signals (PWM1 and PWM2) 702 and 704, which are received at control inputs 120 and 132, respectively. The signal diagram also includes enable signals (EN1 and EN2) 706 and 708. In the example of FIG. 2, the enable signals 706 and 708 can correspond to the enable signal provided at 216 (for the open fault detection circuitry 114, 116, 200 in power stages 102 and 104), which selectively enables or disables the comparator for detecting the open fault condition. In the example of FIG. 3, the enable signals 706 and 708 can correspond to the enable signal provided at 332 (for the open fault detection circuitry 114, 116, 200 in power stages 102 and 104) to control whether a fault condition (if detected) will be reported at 338. The signal diagram 700 also shows comparator output signals (COMP OUT 1, COMP OUT 2 and COMP OUT 2′) 710, 712 and 714, which are representative of the comparator output at 208 (FIG. 2) or at 308 (FIG. 3) for the open fault detection circuitry 114, 116, 200 in respective first and second power stages 102 and 104. The comparator signal COMP OUT 2 714 represents the output of the comparator in the absence of a fault condition and COMP OUT 2′ 712 represents the comparator output when an open fault condition is detected.

As a further example, operation of the open fault detection circuitry 114, 116, 200 is activated at bootup of the power stages 102 and 104. Post bootup, at time T1, the enable signals EN1 and EN2 go high to enable the comparators 202, 302 of each power stage to compare the switching voltage VSW relative to the reference voltage, such as to detect for transitions in VSW voltage as described herein. The controller 130 provides PWM1 (for activating a first power stage). The controller can first activate any of the power stages to provide a corresponding phase voltage at its switching output. In the example of FIG. 7, the PWM1 signal goes high at time T2, which induces current on the secondary winding 180 (e.g., induced current di/dt=(Vin−nVout)/Lc, where n represents the phase number). For the first power stage 102, at time T2, responsive to the first PWM transitioning from PWM Tristate to PWM High state, the enable signal 706 goes low to disable the comparator and/or reporting of an open fault condition for the first power stage. When there is no open fault condition, the induced current is coupled onto the other phases (from the secondary to the primary windings), which turns on body diode, such that the VSW for each other phase approximates a negative body diode voltage. Also assuming no open fault condition occurs, the comparator of the second stage detects the transition in VSW responsive to the induced current and the comparator output remains low (e.g., unasserted), such as shown at 714. The flip-flop 318 can latch the information to the output 320. However, no action is necessary by the controller 130 because no fault condition has been detected. In examples where an open fault condition occurs, as shown in the COMP OUT 2 signal 712, there is no induced voltage at VSW of the other power stages such that comparator output goes high (e.g., is asserted), such as shown at 716. Because this occurs while the enable signal 708 for the stage is also high, the latched comparator signal indicating the detected fault condition can be used to provide a signal at the report output of the stage for indicating the detected fault. In response to the fault detection signal being flagged at the report output, the controller ascertains that the detected open fault condition for the second power stage 104 and performs action to reduce or prevent damage. In one example, the controller 130 can provide a control signal to turn off or deactivate power supply rails and/or command each phase off by sending a command to transition from PWM Tristate to PWM Low state (e.g., for a specified duration or until the fault condition has been corrected or at reboot of the power system).

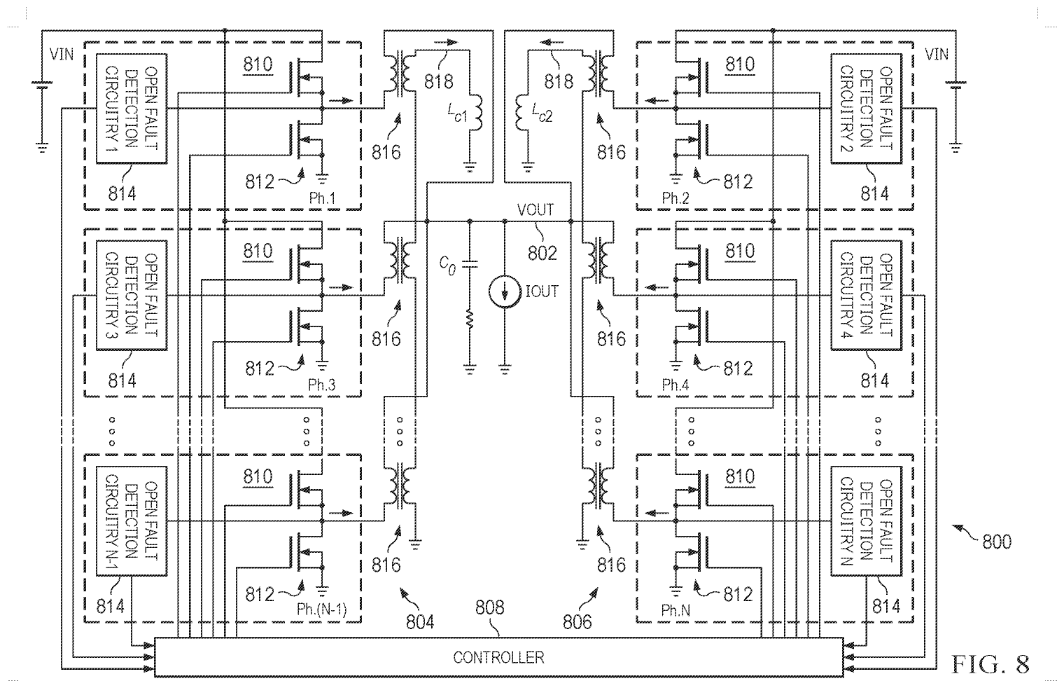

FIG. 8 is a circuit diagram illustrating an example multiphase power converter 800 configured as a DC-DC converter to provide an output voltage VOUT and output current IOUT at an output terminal 802. The example power converter 800 in FIG. 8 includes two power loops (e.g., partitions) 804 and 806, a controller, and plurality of power stages 810, shown as phases 1 through N. Each of the power loops 804 and 806 is are coupled to the output terminal 802. The multiphase power converter 800 can include any number of one or more power loops having a number of power stages 810. The controller 808 can be an instance of the controller 130 of FIG. 1.

Each power stage 810 can be an instance of the power stage 102, 104, 106 described herein. For example, each power stage 810 includes switching circuitry 812 that includes transistors (e.g., FETs) arranged as a half-bridge circuit coupled between an input voltage supply (VIN) and ground. The power stages 810 also include open fault detection circuitry 814, which can be implemented as any open fault detection circuitry 114, 116, 118, 200, 300 described herein. Thus, each open fault detection circuitry 814 has an input coupled to a switching output of the respective power stage 810 and an output coupled to the controller 808. In an example, each power stage 810 and the controller 808 is implemented as a respective IC, which can be coupled to each other through conductive traces on one or more printed circuit boards. The power stages 810 can also include other circuitry, such as sensing circuitry, which can share a common terminal of the respective power stage IC with the open fault detection circuitry, as described herein (see, e.g., FIG. 3). The switching output of each power stage 810 is coupled to the output terminal 802 through a primary winding of a respective transformer 816. The secondary windings of the transformers 816 in each power loop 804 and 806 are coupled in series with a compensation inductor LC1 and LC2 to define a respective loop compensation path 818 (e.g., compensation path 186).

The controller 808 is configured to provide control signals (e.g., PWM control signals) to the switching circuitry 812 of respective phases to regulate the output voltage VOUT at the output terminal 802. As described herein, the open fault detection circuitry 814 can be configured to detect and/or report an open fault condition in the compensation path 818 based on the phase switching voltage and control signals for each respective phase. For example, when switching circuitry 812 of a given phase is turned off during startup, the open fault detection circuitry 814 of the given phase is enabled to detect and/or report a detected fault. Conversely, when switching circuitry 812 of a given phase is turned on during startup to provide the phase voltage, the open fault detection circuitry 814 of the given phase can be disabled from detecting and/or reporting the occurrence of a detected fault. The controller 808 can be configured to implement corrective action in response to receiving an open fault detection signal indicating the occurrence of an open fault condition in a respective compensation path 818, such as described herein.

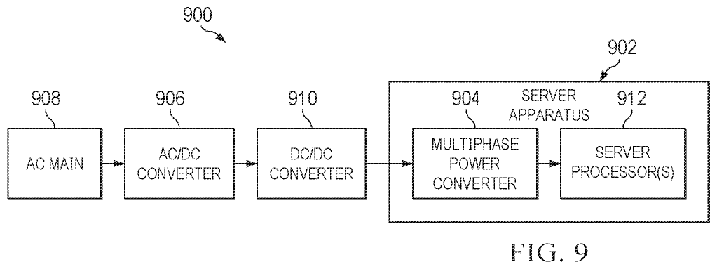

FIG. 9 is a block diagram illustrating power system 900 for a computing system, which is shown as a server apparatus 902 implementing an example multiphase power converter 904. The multiphase power converter 904 can be implemented according to any of the example embodiments described herein (see, e.g., FIGS. 1-8). The power system 900 includes an AC/DC converter 906 coupled to an input AC main power source 908. A DC/DC converter 910 has an input coupled to a DC output of the AC/DC converter 906. The multiphase power converter 904 has an input coupled to the DC/DC converter 910 to receive DC power. The multiphase power converter 904 includes a controller and a plurality of power stages. At least some of power stages includes an open fault detection configured to detect an open fault condition as described herein and the controller (or other circuitry) is configured to perform protective action, which can help prevent damage and ensure improved performance of the load(s), including one or more server processors 912 of the server apparatus 902, being powered by the multiphase power converter 904. Other types and configurations of power system can use the multiphase power converter 904 to supply power to various other types of loads based on this description.

In this description, the term “couple” or “couples” means either an indirect or direct connection. Thus, if a first device couples to a second device, that connection may be through a direct connection or through an indirect connection via other devices and connections. For example, if device A generates a signal to control device B to perform an action, then: (a) in a first example, device A is coupled to device B; or (b) in a second example, device A is coupled to device B through intervening component C if intervening component C does not alter the functional relationship between device A and device B, so device B is controlled by device A via the control signal generated by device A.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof. Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A circuit, comprising:
a first power stage comprising:
first switching circuitry having a first control input and a first switching output; and
first open fault detection circuitry having first detection input and a first reference input, in which the first detection input is coupled to the first switching output and the first reference input is coupled to a reference voltage terminal;
a second power stage comprising:
second switching circuitry having a second control input and a second switching output; and
second open fault detection circuitry having third and fourth inputs, in which the third input is coupled to the second switching output and the fourth input is coupled to the reference voltage terminal.

2. The circuit of claim 1, wherein the first open fault detection circuitry includes:
a comparator having first and second comparator inputs and a comparator output, in which the first comparator input is coupled to the first detection input and the second comparator input is coupled to the first reference input; and
logic circuitry having first and second logic inputs and a logic output, in which the first logic input is coupled to the comparator output, the second logic input coupled to the first control input, and the logic output is coupled to a report terminal.

3. The circuit of claim 2, wherein the comparator is configured to provide a comparator output signal at the comparator output indicating an open fault condition responsive to a signal at the first switching output relative to a reference signal at the first reference input, and the logic circuitry is configured to control reporting of the open fault condition based on the comparator output signal and responsive to a control signal at the first control input.

4. The circuit of claim 1, wherein the first open fault detection circuitry includes phase detection control logic having a detection control input, a detection control output and a report terminal, the detection control input is coupled to the first control input, and the phase detection control logic is configured to enable the first open fault detection circuitry to report an open fault condition at the report terminal responsive to a signal at the detection control input.

5. The circuit of claim 4, wherein the signal at the detection control input is a tri-state pulse-width modulated (PWM) signal, and the phase detection control logic is configured to:
enable the first open fault detection circuitry to report the open fault condition at the report terminal in response to detecting a first transition in the PWM signal to turn on the first switching circuitry, and
disable the first open fault detection circuitry from reporting the open fault condition at the report terminal in response to detecting a second transition in the PWM signal.

6. The circuit of claim 1, further comprising a controller having first and second control outputs and first and second sense terminals, in which the first control output is coupled to the first control input, the second control output is coupled to the second control input, the first sense terminal is coupled to a report output of the first power stage, and the second sense terminal is coupled to a report output of the second power stage.

7. The circuit of claim 6, further comprising:
a first transformer having respective primary and secondary windings, in which the primary winding of the first transformer is coupled between the first switching output and an output terminal; and
a second transformer having respective primary and secondary windings, in which the primary winding of the second transformer is coupled between the second switching output and the output terminal,
wherein the secondary windings of the first and second transformers are coupled in series with a compensation inductor to define a compensation path.

8. The circuit of claim 7, wherein:
the first power stage includes a first current sense circuit configured to provide a first current sense signal at the report output of the first power stage representative of a measure of current through the primary winding of the first transformer,
the second power stage includes a second current sense circuit configured to provide a second current sense signal at the report output of the second stage representative of a measure of current through the primary winding of the second transformer, and
the controller is configured to:
detect an open fault condition in the compensation path or determine the measure of current through the primary winding of the first transformer based on a signal at the first sense terminal; and
detect the open fault condition or determine the measure of current through the primary winding of the second transformer based on a signal at the second sense terminal.

9. The circuit of claim 8, wherein each of the first power stage and the second power stage has a respective power input coupled to a supply voltage terminal, and the controller is configured to turn off a supply voltage provided to the supply voltage terminal responsive to detecting the open fault condition.

10. A multiphase power converter circuit, comprising:
a first power stage configured to provide a first phase output signal at a first switching output based on a first control signal, the first power stage including first open fault detection circuitry configured to disable detecting and/or reporting of an open fault condition responsive to the first control signal having a value to turn on the first power stage; and
a second power stage configured to provide a second phase output signal at a second switching output based on a second control signal, the second power stage including second open fault detection circuitry configured to enable detecting and/or reporting of the open fault condition responsive to the second control signal having a value to turn off the second power stage, and the second open fault detection circuitry is configured to detect the open fault condition based on a voltage at the second switching output.

11. The circuit of claim 10, wherein the first open fault detection circuitry is configured to detect the open fault condition based on a voltage at the first switching output responsive to the first control signal having the value to turn off the first power stage during a start-up mode of the multiphase power converter circuit.

12. The circuit of claim 10, wherein the multiphase power converter circuit has an output terminal, and the circuit further comprises:
a first transformer having respective primary and secondary windings, in which the primary winding is coupled between the first switching output and the output terminal; and
a second transformer having respective primary and secondary windings, in which the primary winding is coupled between the second switching output and the output terminal,
wherein the secondary windings of the first and second transformers are coupled in series with a compensation inductor to provide a compensation path.

13. The circuit of claim 12, wherein the second phase output signal is a second phase voltage and the second open fault detection circuitry comprises:
a comparator configured to provide a comparator output signal indicating a detected open fault condition in the compensation path based on a reference voltage and the voltage at the second switching output.

14. The circuit of claim 13, wherein the second open fault detection circuitry comprises phase detection control logic configured to enable the second open fault detection circuitry to provide an open fault detection signal indicating the detected open fault condition responsive to the second control signal having the value to turn off the second power stage.

15. The circuit of claim 14, wherein the second control signal is a tri-state pulse-width modulated (PWM) signal, and the phase detection control logic is configured to:
enable the second open fault detection circuitry to provide the open fault detection signal responsive to detecting a first transition in the PWM signal commanding the second power stage to turn off, and
disable the second open fault detection circuitry from providing the open fault detection signal responsive to detecting a second transition in the PWM signal commanding the second power stage to turn on.

16. The circuit of claim 12, further comprising:
a controller configured to provide the first and second control signals to regulate a voltage at the output terminal.

17. The circuit of claim 16, wherein:
the first power stage includes a first current sense circuit configured to provide a first current sense signal at a report output of the first stage representative of a measure of current through the primary winding of the first transformer,
the second power stage includes a second current sense circuit configured to provide a second current sense signal at a report output of the second stage representative of a measure of current through the primary winding of the second transformer, and
the controller includes first and second sense terminals, in which the first sense terminal coupled to the report output of the first power stage, the second sense terminal is coupled to the report output of the second power stage, and the controller is configured to:
detect the open fault condition in the compensation path or determine the measure of current through the primary winding of the first transformer based on a signal at the first sense terminal; and
detect the open fault condition in the compensation path or determine the measure of current through the primary winding of the second transformer based on a signal at the second sense terminal.

18. The circuit of claim 17, wherein each of the first power stage and the second power stage has a respective power input coupled to a supply voltage terminal, and the controller is configured to turn off a supply voltage provided to the supply voltage terminal responsive to detecting the open fault condition.

19. A circuit comprising:
a power stage comprising:
switching circuitry configured to provide a voltage at a switching output responsive to a control signal; and
open fault detection circuitry comprising:
a comparator configured to provide a comparator output signal indicating a detected open fault condition in based on a reference voltage and the voltage at the switching output; and
phase detection control logic configured to enable the open fault detection circuitry to provide an open fault detection signal indicating the detected open fault condition responsive to the control signal having a value to turn off the switching circuitry.

20. The circuit of claim 19, wherein:
the control signal is a tri-state pulse-width modulated (PWM) signal,
the switching circuitry is a half-bridge circuit including respective first and second transistors, in which first and second transistors are coupled together at a juncture that defines the switching output, and
the phase detection control logic is configured to:
enable the open fault detection circuitry to provide the open fault detection signal at a report terminal thereof in response to detecting a first transition in the PWM signal commanding the power stage to turn off, and
disable the open fault detection circuitry from providing the open fault detection signal responsive to detecting a second transition in the PWM signal commanding the second power stage to turn on.

21. The circuit of claim 19, wherein the power stage is a first instance of the power stage, the switching output is a first switching output, the control signal is a first control signal, the voltage is a first phase voltage, the first instance of the power stage is configured to provide the first phase voltage at the first switching output based on the first control signal, and the circuit further comprises:
a second instance of the power stage configured to provide a second phase voltage at a second switching output based on a second control signal;
a first transformer having respective primary and secondary windings, in which the primary winding of the first transformer is coupled between the first switching output and an output terminal; and
a second transformer having respective primary and secondary windings, in which the primary winding of the second transformer is coupled between the second switching output and the output terminal, wherein the secondary windings of the first and second transformers are coupled in series with a compensation inductor to define a compensation path; and
a controller configured to provide the first and second control signals to regulate a voltage at the output terminal based on the first and second phase voltages.

22. The circuit of claim 21, wherein:
the first instance of the power stage includes a first current sense circuit configured to provide a first current sense signal at a first report output thereof representative of a measure of current through the primary winding of the first transformer,
the second instance of the power stage includes a second current sense circuit configured to provide a second current sense signal at a second report output thereof representative of a measure of current through the primary winding of the second transformer, and
the controller includes first and second sense terminals, in which the first sense terminal coupled to the report output of the first instance of the power stage, the second sense terminal is coupled to a report output of the second instance of the power stage, and the controller is configured to:
detect an open fault condition in the compensation path or determine the measure of current through the primary winding of the first transformer based on a signal at the first sense terminal; and
detect the open fault condition in the compensation path or determine the measure of current through the primary winding of the second transformer based on a signal at the second sense terminal.

23. The circuit of claim 19, further comprising an integrated circuit that includes the power stage encapsulated in a molding compound.
